(19) United States
(12) Patent Application Publication
(10) Pub. No.: US 2018/0068736 A1
(43) Pub. Date: Mar. 8, 2018

(54) MEMORY SYSTEM AND METHOD FOR OPERATING THE MEMORY SYSTEM

(71) Applicant: SK hynix Inc., Gyeonggi-do (KR)

(72) Inventor: Kyung-Bum KIM, Gyeonggi-do (KR)

(21) Appl. No.: 15/478,529

(22) Filed: Apr. 4, 2017

(30) Foreign Application Priority Data
Sep. 5, 2016 (KR) 10-2016-0113718

(51) Int. Cl. G11C 16/34; G11C 16/28

(52) U.S. Cl. CPC G11C 16/3431; G11C 16/28

(57) ABSTRACT

A memory system includes: a memory device; and a controller that is functionally coupled to the memory device, wherein the controller sets a first read bias for distinguishing erased cells and programmed cells from each other, and detects the number of cells that are read in the memory device by controlling a read operation of the memory device based on the first read bias, analyzes the detected number of the cells with the number of reference cells, and when the number of the cells that are read goes out of an error tolerance range, generates a second read bias by offsetting the first read bias.

### CROSS-REFERENCE TO RELATED APPLICATIONS

The present application claims priority of Korean Patent Application No. 10-2016-0113718, filed on Sep. 5, 2016, which is incorporated herein by reference in its entirety.

### BACKGROUND

### 1. Field

Exemplary embodiments of the present invention relate to a memory system, and more particularly, to a memory system capable of setting a read bias and a method for operating the memory system.

### 2. Description of the Related Art

Recently, the paradigm of the computer environment is changed into a ubiquitous computing environment which allows users to get an access to a computer system anywhere and anytime. For this reason, use of portable electronic devices, such as mobile phones, digital cameras, laptop computers and the like, is surging. Portable electronic devices generally employ a memory system using a memory device for storing data, i.e., as a data storage device. A data storage device may be used as a main memory device or an auxiliary memory device of a portable electronic device.

A data storage device using a memory device has excellent stability and durability because the data storage device does not include a mechanical driving unit. Also, the data storage device using a memory device is advantageous in that it may access data quickly and consume a small amount of power. Non-limiting examples of a data storage device having these advantages include a Universal Serial Bus (USB) memory device, a memory card with various interfaces, a Solid-State Drive (SSD) and so forth.

### SUMMARY

When a read operation is performed in a memory system and a read bias is recognized as an inadequate read bias, the read operation may be resumed after setting an initial bias. When a memory system determines the initial bias, the initial bias that is determined in a situation where an erase state distribution is changed may go out of an adequate read bias range. Hereafter, the initial bias may also be referred to as a first read bias, and a read bias obtained by adjusting the first read bias may also be referred to as a second read bias.

Embodiments of the present invention are directed to a memory system that can determine the adequacy of a first read bias, and can generate a second read bias by adjusting an offset of the first read bias when the first read bias is determined to be inadequate. The first read bias may be determined by employing a Gaussian modeling algorithm.

Embodiments of the present invention are directed to a memory system that may determine the adequacy of the first read bias by counting the number of cells that are positioned on the left side (disposed in the direction lower than the first read bias) of the first read bias which is determined based on the Gaussian modeling algorithm, and analyzing the counted number of the cells and the reference cell number.

Embodiments of the present invention are directed to a memory system that, when the first read bias is determined to be inadequate, may generate the second read bias by offsetting the first read bias in a negative direction or a positive direction based on an error rate of the counted number of the cells and a reference cell number.

In accordance with an embodiment of the present invention, a memory system includes: a memory device; and a controller coupled to the memory device, wherein the controller determines a first read bias for distinguishing erased cells and programmed cells from each other, and detects the number of cells that are read in the memory device by controlling a read operation of the memory device based on the first read bias, and when the number of the cells that are read goes out of an error tolerance range, generates a second read bias by offsetting the first read bias.

The first read bias may be set based on a Gaussian modeling algorithm.

The first read bias may have a voltage level that is lower than a threshold voltage of the programmed cells and higher than a threshold voltage of the erased cells.

The controller may include: a read bias determination unit suitable for determining the first read bias based on the Gaussian modeling algorithm; an adequacy determination unit suitable for analyzing the number of erased cells that are read based on the first read bias and a reference cell number and determining whether the first read bias is an adequate read bias or not; and a read bias control unit suitable for, when the first read bias is not an adequate read bias, generating the second read bias by offsetting the first read bias based on an error rate.

The read bias control unit may generate the second read bias by offsetting the first read bias in a positive direction when the number of the erased cells that are read is greater than the reference cell number, and wherein the read bias control unit may generate the second read bias by offsetting the first read bias in a negative direction when the number of the erased cells that are read is smaller than the reference cell number.

The controller may detect the number of cells that are positioned on a left side of the first read bias among the cells that are read based on the first read bias in the memory device, and determine whether the first read bias is an adequate read bias or not by analyzing the detected number of the cells and the reference cell number.

The controller may generate the second read bias by offsetting the first read bias in a positive direction when the first read bias is determined to be an inadequate read bias and the detected number of the cells is greater than the reference cell number, and wherein the controller may generate the second read bias by offsetting the first read bias in a negative direction when the first read bias is determined to be an inadequate read bias and the detected number of the cells is smaller than the reference cell number.

The controller may control a read operation of the memory device based on the second read bias, detect the number of cells that are positioned on a left side of the second read bias among the cells that are read in the memory device, and determine whether the second read bias is an adequate read bias or not by analyzing the detected number of the cells that are positioned on the left side of the second read bias and the reference cell number.

When the first read bias or the second read bias is determined to be an adequate read bias, the controller may control a read operation of the memory device by setting the adequate read bias as a read bias of the memory device.

The controller may control the read operation of the memory device based on the set read bias, and control the read bias based on a Gradient descent algorithm during the read operation of the memory device.

In accordance with another embodiment of the present invention, a memory system includes: a memory device; and a controller coupled to the memory device, wherein the controller determines a first read bias for distinguishing erased cells and programmed cells from each other based on a Gaussian modeling algorithm, controls a read operation of the memory device based on the first read bias, compares the number of cells that are read in the memory device with a reference cell number that is based on the erased cells, and when the number of the cells that are read goes out of an error tolerance range and the number of the cells that are read is smaller than the reference cell number, generates a second read bias by offsetting the first read bias in a positive direction, and when the number of the cells that are read goes out of an error tolerance range and the number of the cells that are read is greater than the reference cell number, generates a second read bias by offsetting the first read bias in a negative direction.

When the number of the cells that are read is within an error tolerance range, the controller may set the first read bias as a read bias and perform a read operation.

In accordance with yet another embodiment of the present invention, a method for operating a memory system includes: determining a first read bias for distinguishing erased cells and programmed cells from each other; controlling a read operation of a memory device based on the first read bias; detecting the number of cells that are read in the memory device; and when the number of the cells that are read goes out of an error tolerance range, generating a second read bias by offsetting the first read bias.

The first read bias may be set based on a Gaussian modeling algorithm.

The first read bias may have a voltage level that is lower than a threshold voltage of the programmed cells and higher than a threshold voltage of the erased cells.

The method may further include: determining the generated second read bias as a read bias of the memory device; and controlling a read operation of the memory device based on the set read bias.

The generating of the second read bias by offsetting the first read bias may include: analyzing the number of erased cells that are read based on the first read bias and a reference cell number; determining whether the first read bias is an adequate read bias or not; and when the first read bias is determined to be an inadequate read bias, generating the second read bias by offsetting the first read bias based on an error rate.

The generating of the second read bias by offsetting the first read bias may include: offsetting the first read bias in a positive direction when the number of the erased cells that are read based on the first read bias is greater than the reference cell number; and offsetting the first read bias in a negative direction when the number of the erased cells that are read based on the first read bias is smaller than the reference cell number.

The method may further include: controlling the read operation of the memory device based on the second read bias, after the setting of the generated second read bias as the read bias of the memory device; detecting the number of cells that are positioned on a left side of the second read bias among the cells that are read in the memory device; and determining whether the second read bias is an adequate read bias or not by analyzing the detected number of the cells and the reference cell number.

The controlling of the read operation may further include: updating the read bias based on the Gradient descent algorithm.

### BRIEF DESCRIPTION OF THE DRAWINGS

FIG. 1 is a block diagram illustrating a data processing system including a memory system, in accordance with an embodiment of the present invention.

FIG. 2 illustrates a memory device in a memory system, in accordance with an embodiment of the present invention.

FIG. 3 is a block diagram illustrating a memory cell array circuit of memory blocks in a memory device, in accordance with an embodiment of the present invention.

FIG. 4 illustrates a structure of a memory device in a memory system, in accordance with an embodiment of the present invention.

FIG. 5 illustrates a memory system, in accordance with an embodiment of the present invention.

FIG. 6 is a block diagram illustrating a memory device, in accordance with an embodiment of the present invention.

FIGS. 7A to 7C are diagrams illustrating threshold voltage distributions of an erased state and higher data states of a memory device in a memory system, in accordance with an embodiment of the present invention.

FIGS. 8A to 8C are diagrams illustrating an operation for determining a first read bias in the memory system, in accordance with an embodiment of the present invention.

FIG. 9 is a flowchart illustrating an operation for determining a read bias in the memory system, in accordance with an embodiment of the present invention.

FIG. 10 is a flowchart illustrating an operation for determining a first read bias in the memory system, in accordance with an embodiment of the present invention.

FIG. 11 is a flowchart illustrating an operation for determining a read bias between a controller and a memory device in the memory system, in accordance with an embodiment of the present invention.

FIG. 12 is a flowchart illustrating a process of performing a read operation in the memory system, in accordance with an embodiment of the present invention.

FIGS. 13 to 18 illustrates various examples of a data processing system including the memory system, in accordance with various embodiments of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

It is noted that the drawings are simplified schematics and as such are not necessarily drawn to scale. In some instances, various parts of the drawings may have been exaggerated in order to more clearly illustrate certain features of the illustrated embodiments.

It is further noted that in the following description, specific details are set forth for facilitating the understanding of the present invention, however, the present invention may be practiced without some of these specific details. Also, it is noted, that well-known structures and/or processes may have only been described briefly or not described at all to avoid obscuring the present disclosure with unnecessary well known details.

It is also noted, that in some instances, as would be apparent to those skilled in the relevant art, an element (also referred to as a feature) described in connection with one embodiment may be used singly or in combination with other elements of another embodiment, unless specifically indicated otherwise.

Hereinafter, the various embodiments of the present invention will be described in detail with reference to the attached drawings.

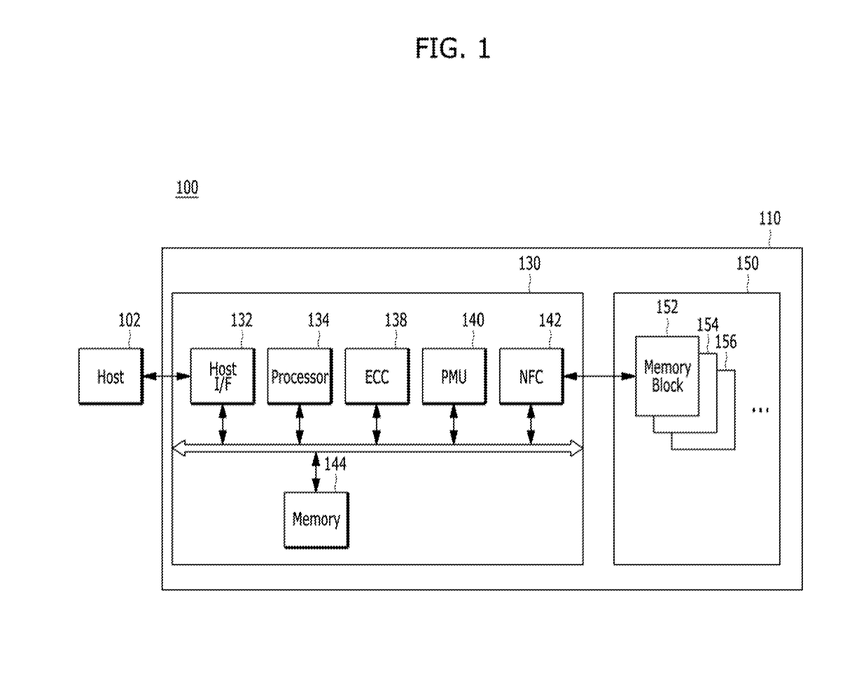

FIG. 1 illustrates a data processing system 100 including a memory system 110, according to an embodiment of the present invention.

Referring to FIG. 1, the data processing system 100 may also include a host 102 operatively coupled to the memory system 110.

The host 102 may be any suitable electronic device. The host 102 may be or include, for example, a portable electronic device such as a mobile phone, an MP3 player and a laptop computer or a non-portable electronic device such as a desktop computer, a game player, a television (TV) and a projector.

The memory system 110 may operate in response to a request from the host 102. For example, the memory system 110 may store data provided by the host 102 and the memory system 110 may also provide stored data to the host 102. Data which are stored in the memory system may be accessed by the host 102. The memory system 110 may be used as a main memory or an auxiliary memory of the host 102. The memory system 110 may be implemented with any one of various storage devices, according to the protocol of a host interface to be coupled electrically with the host 102. The memory system 110 may be implemented with any one of various storage devices such as, for example, a solid state drive (SSD), a multimedia card (MMC), an embedded MMC (eMMC), a reduced size MMC (RS-MMC), a micro-MMC, a secure digital (SD) card, a mini-SD, a micro-SD, a universal serial bus (USB) storage device, a universal flash storage (UFS) device, a compact flash (CF) card, a smart media (SM) card, a memory stick, and the like.

The storage devices forming the memory system 110 may be implemented with a volatile memory device, such as a dynamic random access memory (DRAM) and a static random access memory (SRAM) or a nonvolatile memory device, such as a read only memory (ROM), a mask ROM (MROM), a programmable ROM (PROM), an erasable programmable ROM (EPROM), an electrically erasable programmable ROM (EEPROM), a ferroelectric random access memory (FRAM), a phase-change RAM (PRAM), a magnetoresistive RAM (MRAM), a resistive RAM (RRAM) and a flash memory.

The memory system 110 may include a memory device 150 and a controller 130. The memory device 150 may store data which may be accessed by the host 102. The controller 130 may control data exchange between the memory device 150 and the host 102. For example, under the control of the controller 130, data received from the host 102 may be stored in the memory device 150, and stored data in the memory device 150 may be read and transmitted to the host 102.

The controller 130 and the memory device 150 may be integrated into one semiconductor device. For instance, the controller 130 and the memory device 150 may be integrated into one semiconductor device to form a solid state drive (SSD). When the memory system 110 is used as an SSD, the operation speed of the host 102 that is electrically coupled with the memory system 110 may be significantly increased.

The controller 130 and the memory device 150 may be integrated into one semiconductor device to form a memory card, such as, for example, a Personal Computer Memory Card International Association (PCMCIA) card, a compact flash (CF) card, a smart media card (SMC), a memory stick, a multimedia card (MMC), an RS-MMC, a micro-MMC, a secure digital (SD) card, a mini-SD, a micro-SD, an SDHC, and a universal flash storage (UFS) device.

In another instance, the memory system 110 may be or may be included in a computer, an ultra-mobile PC (UMPC), a workstation, a net-book, a personal digital assistant (PDA), a portable computer, a web tablet, a tablet computer, a wireless phone, a mobile phone, a smart phone, an e-book, a portable multimedia player (PMP), a portable game player, a navigation device, a black box, a digital camera, a digital multimedia broadcasting (DMB) player, a three-dimensional (3D) television, a smart television, a digital audio recorder, a digital audio player, a digital picture recorder, a digital picture player, a digital video recorder, a digital video player, a storage for a data center, a device capable of transmitting and receiving information under a wireless environment, one of various electronic devices for a home network, one of various electronic devices for a computer network, one of various electronic devices for a telematics network, an RFID device, or one of various component elements for a computing system.

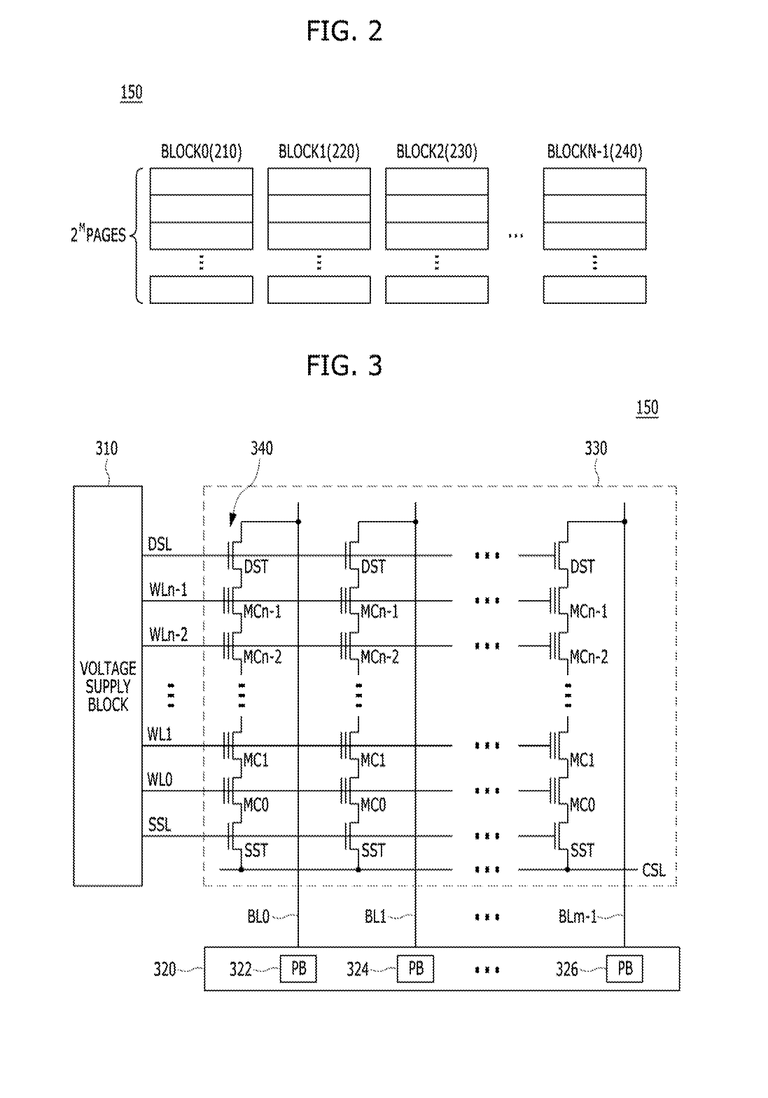

The memory device 150 may retain stored data even when power is blocked, store the data provided from the host 102 during a write operation, and provide stored data to the host 102 during a read operation. The memory device 150 may include a plurality of memory blocks 152, 154 and 156. Each of the memory blocks 152, 154 and 156 may include a plurality of pages. Each of the pages may include a plurality of memory cells which are electrically coupled to a word line (WL). The memory cells may be single bit cells or multi-bit cells. The memory cells may be arranged in a two or three dimensional stacked structure. The memory device 150 may be a nonvolatile memory device, for example, a flash memory. The flash memory may have a three-dimensional (3D) stack structure. An exemplary configuration of the memory device 150 and an exemplary three-dimensional (3D) stack structure of the memory device 150 will be described later in detail with reference to FIGS. 2 to 4.

The controller 130 of the memory system 110 may control the memory device 150 in response to a request from the host 102. The controller 130 may provide the data read from the memory device 150, to the host 102, and store the data provided from the host 102 into the memory device 150. To this end, the controller 130 may control the overall operations of the memory device 150 including operations such as read, write, program, and erase operations.

For example, the controller 130 may include a host interface (I/F) unit 132, a processor 134, an error correction code (ECC) unit 138, a power management unit (PMU) 140, a NAND flash controller (NFC) 142, and a memory 144.

The host interface unit 132 may process commands and data provided from the host 102, and may communicate with the host 102 through at least one of various interface protocols such as universal serial bus (USB), multimedia card (MMC), peripheral component interconnect express (PCI-e), serial attached SCSI (SAS), serial advanced technology attachment (SATA), parallel advanced technology attachment (PATA), small computer system interface (SCSI), enhanced small disk interface (ESDI), and integrated drive electronics (IDE).

The ECC unit 138 may detect and correct errors in the data read from the memory device 150 during the read operation. The ECC unit 138 may not correct error bits when the number of the error bits is greater than a threshold number of correctable error bits, and may output an error correction fail signal indicating failure in correcting the error bits.

The ECC unit 138 may perform an error correction operation based on any suitable method including a coded modulation such as a low density parity check (LDPC) code, a Bose-Chaudhuri-Hocquenghem (BCH) code, a turbo code, a Reed-Solomon (RS) code, a convolution code, a recursive systematic code (RSC), a trellis-coded modulation (TCM), a Block coded modulation (BCM), and so on. The ECC unit 138 may include all circuits, systems or devices for the error correction operation.

The PMU 140 may provide and manage power for the controller 130, that is, power for the component elements included in the controller 130.

The NFC 142 may serve as a memory interface between the controller 130 and the memory device 150 to allow the controller 130 to control the memory device 150 in response to a request from the host 102. The NFC 142 may generate control signals for the memory device 150 and process data under the control of the processor 134 when the memory device 150 is a flash memory and, in particular, when the memory device 150 is a NAND flash memory. It is noted that a different memory interface may be employed depending upon the type of memory device employed.

The memory 144 may serve as a working memory of the memory system 110 and the controller 130. The memory 144 may store data for driving the memory system 110 and the controller 130. The controller 130 may control the memory device 150 in response to a request from the host 102. For example, the controller 130 may provide data read from the memory device 150 to the host 102 and store the data provided from the host 102 in the memory device 150. When the controller 130 controls an operation of the memory device 150 such as, for example, a read, write, program and erase operation, the memory 144 may store data which are used by the controller 130 and the memory device 150 for the operation.

The memory 144 may be implemented with a volatile memory such as, for example, a static random access memory (SRAM) or a dynamic random access memory (DRAM). As described above, the memory 144 may store data used by the host 102 and the memory device 150 for an operation including a read and a write operation. For storing the data, the memory 144 may include a program memory, a data memory, a write buffer, a read buffer, a map buffer, and the like.

The processor 134 may control the general operations of the memory system 110, and a write operation or a read operation for the memory device 150, in response to a write request or a read request received from the host 102, respectively. For example, the processor 134 may drive firmware, which is referred to as a flash translation layer (FTL), to control the general operations of the memory system 110. The processor 134 may be implemented, for example, with a microprocessor or a central processing unit (CPU).

A management unit (not shown) may be included in the processor 134 for performing bad block management of the memory device 150. The management unit may find bad memory blocks included in the memory device 150, which are in unsatisfactory condition for further use, and perform bad block management on the bad memory blocks. When the memory device 150 is a flash memory, for example, a NAND flash memory, a program failure may occur during a program operation, due to characteristics of a NAND logic function. During the bad block management, the data of the program-failed memory block or the bad memory block may be programmed into a new memory block. Bad blocks due to program fails may seriously deteriorate the utilization efficiency of a 3D stack structure memory device 150 and the reliability of the memory system 100, and thus reliable bad block management is typically employed. Bad block management is well known in the art and hence it will not be described herein in any further detail.

FIG. 2 is a diagram illustrating an exemplary configuration of the memory device 150 shown in FIG. 1.

Referring to FIG. 2, the memory device 150 may include a plurality of memory blocks. For example, the memory device 150 may include a zeroth memory block (BLOCK0) 210, a first memory block (BLOCK1) 220, a second memory block (BLOCK2) 230 and an N−1^{th} memory block (BLOCKN−1) 240. Each of the memory blocks 210 to 240 may include a plurality of pages, for example, 2^{M} number of pages (2^{M} PAGES). Each of the pages may include a plurality of memory cells which are electrically coupled to a word line.

Also, the memory device 150 may include a plurality of memory blocks, as single level cell (SLC) memory blocks and/or multi-level cell (MLC) memory blocks, according to the number of bits which may be stored or expressed in each memory cell. The SLC memory block may include a plurality of pages which are implemented with memory cells each capable of storing 1-bit data. The MLC memory block may include a plurality of pages which are implemented with memory cells each capable of storing multi-bit data, for example, two or more-bit data. An MLC memory block including a plurality of pages which are implemented with memory cells that are each capable of storing 3-bit data may also be referred to as a triple level cell (TLC) memory block.

Each of the memory blocks 210 to 240 may store the data provided from the host 102 during a write operation, and provide the stored data to the host 102 during a read operation.

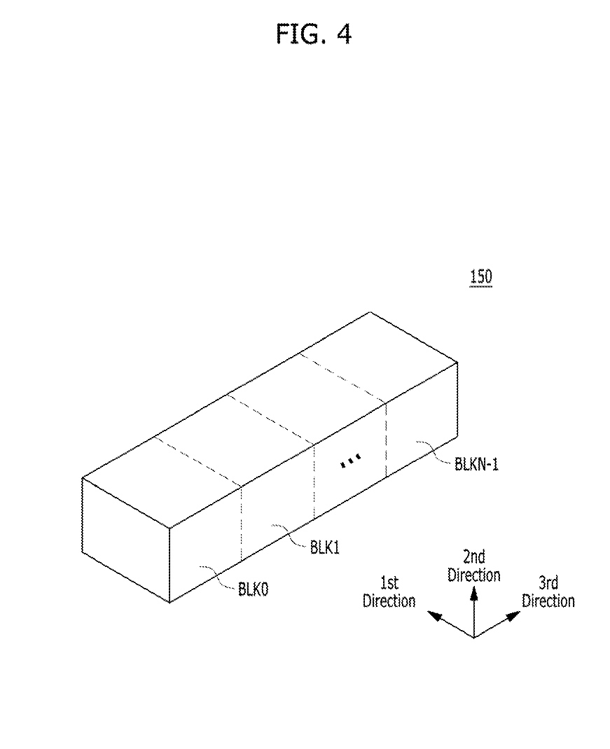

FIG. 3 is a diagram illustrating a memory device 150 including the memory block shown in FIG. 2. For example, FIG. 3 shows a detailed configuration of a single memory block 330 of the memory device 150 and circuits 310 and 320 related thereto.

Referring to FIG. 3, the memory block 330 may include a plurality of cell strings 340 which are electrically coupled to a plurality of corresponding bit lines BL0 to BLm−1, respectively. The cell string 340 of each column may include at least one drain select transistor DST and at least one source select transistor SST. A plurality of memory cell transistors MC0 to MCn−1 may be electrically coupled in series between the select transistors SST and DST. The respective memory cells MC0 to MCn−1 may be configured by multi-level cells (MLC) each of which stores data information of a plurality of bits. For reference, in FIG. 3, ‘DSL’ denotes a drain select line (I.e., a string select line), ‘SSL’ denotes a source select line (i.e., a ground select line), and ‘CSL’ denotes a common source line.

While FIG. 3 shows, as an example, the memory block 330 which is configured by NAND flash memory cells, it is to be noted that the memory block 330 of the memory device 300 is not limited to NAND flash memory. For example, the memory block 330 may also be realized by a NOR flash memory, a hybrid flash memory in which at least two kinds of memory cells are combined, or a one-NAND flash memory in which a controller is built in a memory chip. The operational characteristics of a semiconductor device may be applied to not only a flash memory device in which a charge storing layer is configured by conductive floating gates but also a charge trap flash (CTF) in which a charge storing layer is configured by a dielectric layer.

A voltage supply block 310 of the memory device 300 may provide word line voltages, for example, a program voltage, a read voltage and a pass voltage, to be supplied to respective word lines according to an operation mode and voltages to be supplied to bulks, for example, well regions, where the memory cells are formed. The voltage supply block 310 may perform a voltage generating operation under the control of a control circuit (not shown). The voltage supply block 310 may generate a plurality of variable read voltages to generate a plurality of read data, select one of the memory blocks or sectors of a memory cell array under the control of the control circuit, select one of the word lines of the selected memory block, and provide the word line voltages to the selected word line and unselected word lines.

A read/write circuit 320 of the memory device 300 may be controlled by the control circuit, and may serve as a sense amplifier or a write driver according to an operation mode. During a verification/normal read operation, the read/write circuit 320 may serve as a sense amplifier for reading data from the memory cell array. Also, during a program operation, the read/write circuit 320 may serve as a write driver which drives bit lines according to data to be stored in the memory cell array. The read/write circuit 320 may receive data to be written in the memory cell array, from a buffer (not shown), during the program operation, and may drive the bit lines according to the inputted data. To this end, the read/write circuit 320 may include a plurality of page buffers (PBs) 322, 324 and 326 respectively corresponding to columns (or bit lines) or pairs of columns (or pairs of bit lines), and a plurality of latches (not shown) may be included in each of the page buffers 322, 324 and 326.

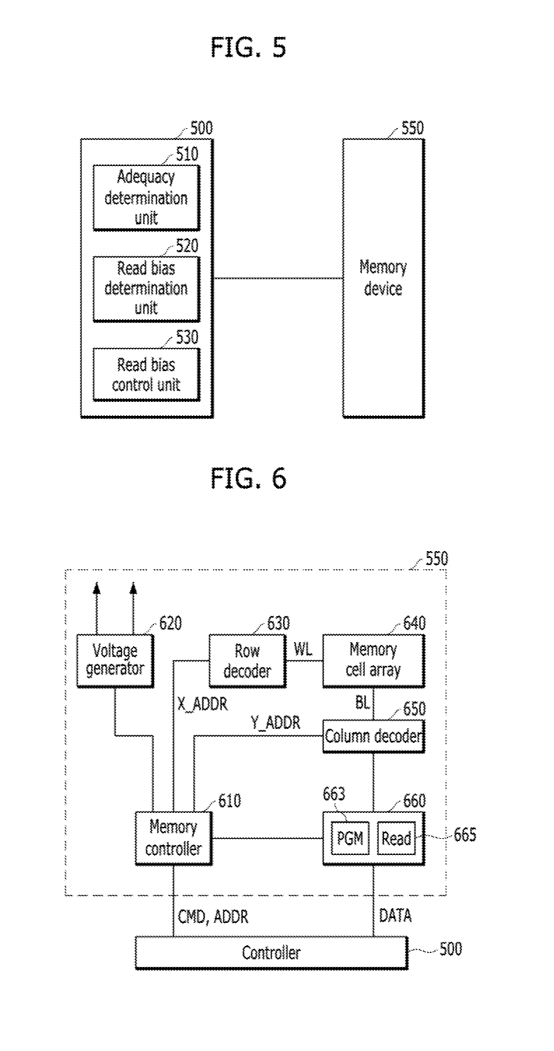

The memory device 150 may be realized as a 2-dimensional or 3-dimensional memory device. For example, as shown in FIG. 4, in the case where the memory device 150 is realized as a 3-dimensional nonvolatile memory device, the memory device 150 may include a plurality of memory blocks BLK0 to BLKN−1.

FIG. 4 is a diagram illustrating the memory blocks BLK0 to BLKN−1 of the memory device 150 shown in FIG. 3, realized as a 3-dimensional structure (or a vertical structure). For example, the respective memory blocks BLK0 to BLKN−1 may be realized as a 3-dimensional structure by including a structure which extends in first to third directions (for example, the x-axis direction, the y-axis direction and the z-axis direction).

The respective memory blocks BLK0 to BLKN−1 may include a plurality of NAND strings extending in the second direction. The plurality of NAND strings may be provided in the first direction and the third direction. Each NAND string may be electrically coupled to a bit line, at least one drain select line, at least one source select line, a plurality of word lines, at least one dummy word line, and a common source line. Namely, the respective memory blocks BLK0 to BLKN−1 may be electrically coupled to a plurality of bit lines, a plurality of drain select lines, a plurality of source select lines, a plurality of word lines, a plurality of dummy word lines, and a plurality of common source lines.

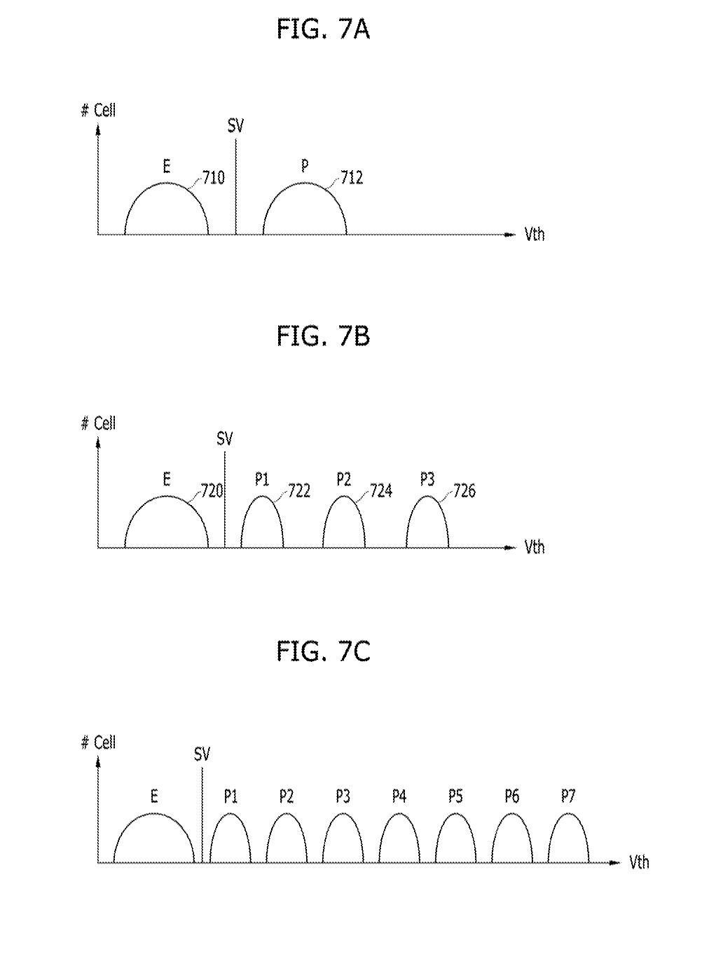

FIG. 5 illustrates a memory system, in accordance with an embodiment of the present invention.

Referring to FIG. 5, the memory system may include a controller 500 and a memory device 550.

The controller 500 may include an adequacy determination unit 510, a read bias determination unit 520, and a read bias control unit 530. The controller 500 may be a controller of an electronic device. The electronic device may include at least one among a smart phone, a tablet Personal Computer (PC), a mobile phone, a video phone, an electronic book reader, a desktop PC, a laptop PC, a netbook computer, a workstation, a server, a Personal Digital Assistant (PDA), a Portable Multimedia Player (PMP), an MP3 (MPEG-1 Audio Layer 3) player, a medical equipment, a camera, and a wearable device.

According to an embodiment of the present invention, the controller 500 may be the controller of a Solid-State Drive (SSD) that is coupled to a host device. The host device may be an electronic device. If the controller 500 is the controller of an SSD, the memory system may be formed to store data provided by an external device in response to a write request of the external device, e.g., the host device. We note that the terms ‘write’ and ‘program’ are used interchangeably. Also, the memory system may provide the external device with the stored data in response to a read request from the external device. The controller 500 may control the general operation of the memory system. The controller 500 may store data in the memory device 550 in response to a write request received from the external device, and read the data stored in the memory device 550 in response to a read request received from the external device and output the data to the external device.

The read bias determination unit 520 may determine an initial bias for controlling a read operation of the memory device 550. The initial bias determination may be based on a Gaussian modeling algorithm. An initial bias may also be referred to as a first read bias. The read bias determination unit 520 may estimate a peak point (i.e., a mean threshold voltage) of threshold voltage distributions, and estimate the width of the threshold voltage distributions at the estimated peak point. For example, the read bias determination unit 520 may determine a point that is positioned on the left apart from the peak point of the threshold voltage distributions by the estimated width as the first read bias. According to an embodiment, the first read bias may be positioned between erased cells and programmed cells. For example, the distribution of the threshold voltages that are positioned on the left side of the target threshold voltage distributions may be threshold voltage distributions of erased cells.

In an embodiment of the present invention, threshold voltage distributions of the erased cells are positioned on the left side (which is a direction toward lower levels than the first read bias) of the first read bias, and threshold voltage distributions of the programmed cells are positioned on the right side (which is a direction toward higher levels than the first read bias) of the first read bias.

Herein, when the threshold voltage distributions of the erased cells are raised, the threshold voltage distributions of the erased cells and the threshold voltage distributions of the programmed cells may partially overlap with each other. When the erase state distribution is raised, the first read bias may get out of an optimal read bias point, which may cause a read failure. The adequacy determination unit 510 may determine the adequacy of a target read bias for the target threshold voltage distributions. According to various embodiments of the present invention, the target read bias may be a first read bias, or a read bias that the memory device 550 is using for a read operation.

The memory device 550 may use a plurality of read biases for a read operation according to the number of the bits stored in one memory cell, and the target read bias may be one or more among the read biases. In other words, the adequacy determination operation may be performed for each of the read biases that are selected as the target read bias among the plurality of read biases. When a target read bias is selected whose adequacy is to be determined, target threshold voltage distributions may be determined corresponding to the target read bias. The target threshold voltage distributions may be threshold voltage distributions that are adjacent to each other among the threshold voltage distributions of memory cells. The target threshold voltage distributions may be the threshold voltage distributions that are positioned adjacent to each other and determined as target read biases among the threshold voltage distributions of the memory cells. In short, the adequacy determination operation may be performed to determine whether the target read bias is properly disposed between the target threshold voltage distributions so that the target read bias is distinguished from the neighboring target threshold voltage distributions. For example, the adequacy determination unit 510 may perform the adequacy determination operation by calculating an error rate of the target read bias with respect to an optimal read bias of the target threshold voltage distributions and determining whether the target read bias is within an error tolerance range for the optimal read bias. The optimal read bias may be a voltage level corresponding to a valley of the target threshold voltage distributions. The target read bias may be determined to be adequate when the target read bias is within the error tolerance range for the optimal read bias. However, when the target read bias is not within the range of the error tolerance range for the optimal read bias, the target read bias may be determined to be inadequate.

The target read bias may be the first read bias that is determined in the read bias determination unit 520. According to an embodiment of the present invention, the target read bias may be a read bias that is used in a read operation. Hereafter, an embodiment of the present invention is described by taking a case, as an example, where the target read bias is the first read bias.

When the adequacy determination unit 510 determines the first read bias to be inadequate, the read bias control unit 530 may generate a second read bias by offsetting (or adjusting) the first read bias into an adequate position. When the number of the cells that are positioned on the left side of the first read bias is smaller than the number of reference cells (also referred to as the reference cell number), the read bias control unit 530 may generate a second read bias that offsets the first read bias in a positive direction. When the number of the cells that are positioned on the left side of the first read bias is greater than the number of the reference cells, the read bias control unit 530 may generate a second read bias that offsets the first read bias in a negative direction. The size of offset of the read bias control unit 530 may be set based on the number of the cells that are positioned on the left side of the first read bias, for example, the error rate that is calculated in the adequacy determination unit 510.

When the read bias control unit 530 generates the second read bias that is obtained by adjusting the first read bias, the controller 500 may generate a voltage control signal based on the second read bias, and transfer the generated voltage control signal to the memory device 550. The memory device 550 may generate a read bias voltage based on the received voltage control signal, and perform a read operation on a target cell based on the generated read bias voltage. The adequacy determination unit 510 of the controller 500 may analyze the number of cells that are read based on the second read bias and determine whether the second read bias is adequate or not. The controller 500 may then control the memory device 550 to perform a read operation based on the second read bias that is determined to be adequate in the adequacy determination unit 510.

According to an embodiment of the present invention, the read bias determination unit 520 may determine the first read bias for distinguishing the erased cells and the programmed cells from each other. The adequacy determination unit 510 may analyze the number of cells that are read based on the read bias voltage obtained by using the determined first read bias to determine the adequacy of the first read bias. When the first read bias goes out of the error tolerance range, that is, the first read bias is not adequate, the read bias control unit 530 may generate the second read bias by adjusting the first read bias.

The memory system of FIG. 5 is illustrated including one memory device 550, but the present invention is not limited to such configuration. It is noted that a plurality of memory devices 550 may be employed without departing from the scope of the present invention.

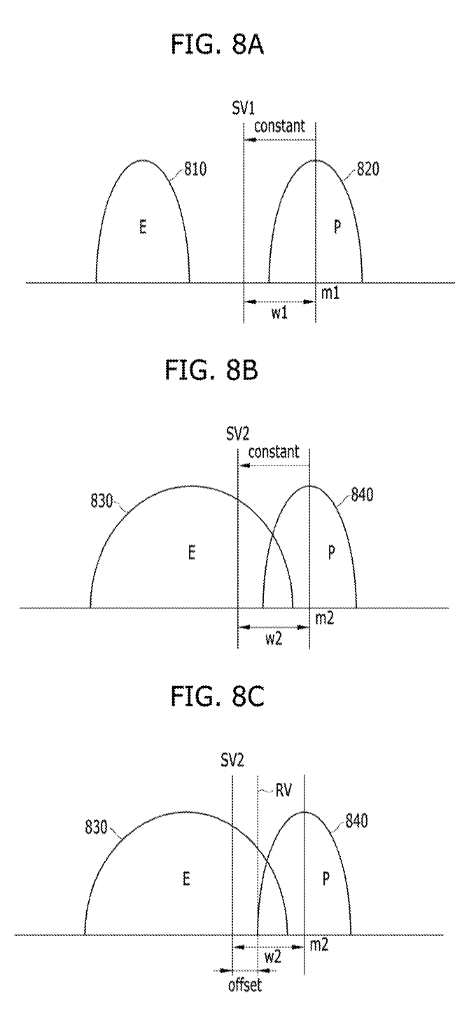

FIG. 6 is a block diagram illustrating a configuration of the memory device 550, in accordance with an embodiment of the present invention.

Referring to FIG. 6, the memory device 550 may include a memory controller 610, a voltage generator 620, a row decoder 630, a memory cell array 640, a column decoder 650, and a program/read circuit 660.

The memory device 550 may include a flash memory device, such as a NAND flash memory device or a NOR flash memory device, a Ferroelectric Random Access Memory (FeRAM), a Phase-Change Random Access Memory (PCRAM), a Magnetic Random Access Memory (MRAM), or a Resistive Random Access Memory (ReRAM). In the following description, the memory device 550 is described as a NAND flash memory device as an exemplary implementation employing a non-volatile memory device.

The memory cell array 640 of the memory device 550 may be coupled to a plurality of word lines WL and a plurality of bit lines BL. Also, the memory cell array 640 may include a plurality of memory cells that are disposed at the cross-points where the word lines WL and the bit lines BL intersect with each other. The memory cell array 640 may receive an address ADDR for indicating a memory cell to be accessed along with a command CMD. For example, the address ADDR may include a row address X_ADDDR for selecting a word line WL of the memory cell array 640 and a column address Y_ADDR for selecting a bit line of the memory cell array 640.

The row decoder 630 may be coupled to the memory cell array 640 through the plurality of word lines WL, and the row decoder 630 may select at least one among the word lines based on the row address X_ADDDR. The column decoder 650 may be coupled to the memory cell array 640 through the bit lines BL, and the column decoder 650 may select at least one among the bit lines based on the column address Y_ADDDR.

The program/read circuit 660 may program (or write) a data DATA inputted from the outside of the memory device 550 into the memory cell array 640 under the control of the memory controller 610, or sense the data programmed in the memory cell array 640 and output the sensed data to the controller 500. Also, the program/read circuit 660 may provide the memory controller 610 with a program result or a read result. For example, the program/read circuit 660 may perform a verification operation to detect a result of a program operation after a program operation is performed, and then the program/read circuit 660 may transfer a signal representing the result of the verification operation, e.g., a pass signal P or a failure signal F, to the memory controller 610.

The program/read circuit 660 may include a program (PGM) circuit 663 and a read circuit 665. The program circuit 663 may be coupled to a selected bit line BL through the column decoder 650 and perform a program operation, which is a data write operation, by transferring a program pulse to a selected memory cell of the memory cell array 640. The read circuit 665 may be coupled to a selected bit line BL through the column decoder 650, and sense the level of a selected memory cell of the memory cell array 640 and read and output the stored data DATA. Also, the read circuit 665 may output the data DATA to the outside of the memory device 550, for example, to the controller 500.

The voltage generator 620 may generate various level of voltages as may be needed for performing a program operation, a read operation, and an erase operation onto the memory cell array 640, based on the voltage control of the memory controller 610. Also, the voltage generator 620 may generate driving voltages (or bias voltages) for driving the word lines WL and the bit lines BL, such as a set program voltage, a reset voltage, a read voltage, and shut-off voltage and the like.

The voltage generator 620 may generate and supply read bias voltages with a corresponding level based on a voltage control signal in a read mode. The voltage control signal may be a voltage control signal based on a first read bias or a second read bias obtained by adjusting the first read bias.

The memory controller 610 may program data in the memory cell array 640 or output voltage control signals for reading data from the memory cell array 640 to the voltage generator 620 based on a command CMD, an address ADDR, and a control signal CTRL that are transferred from the controller 500. Also, the memory controller 610 may supply operation control signals which are received from the controller 500 to the program/read circuit 660, the voltage generator 620, the row decoder 630, and the column decoder 650. Hence, the memory controller 610 may generally control the various operations of the memory device 550.

For example, the memory controller 610 may generate operation control signals based on a command CMD and one or more control signals CTRL that are received from the controller 500, and provide the program/read circuit 660 with the generated operation control signals. Also, the memory controller 610 may provide the row decoder 630 with the row address X_ADDR, and provide the column decoder 650 with the column address Y_ADDR. Also, the memory controller 610 may generate a voltage control signal based on the command CMD, the control signal CTRL, and the pass/failure signal transferred from the read circuit 665 of the program/read circuit 660. For example, the voltage control signal may be a control signal received from the controller 500, and the voltage control signal may include a signal representing an operation mode of the memory device 550 and a signal for controlling the voltage levels of the various voltages that are generated in the voltage generator 620. The memory controller 610 may transfer the voltage control signal to the voltage generator 620.

In a memory system in accordance with an embodiment of the present invention, if the read bias voltage is not adequate at the moment when the read mode starts or while performing a read mode, the controller 500 may generate the first read bias based on the Gaussian modeling algorithm. The controller 500 may output the voltage control signal to the memory device 550 based on the generated first read bias. The memory controller 610 may output the voltage control signal based on the first read bias to the voltage generator 620, and the voltage generator 620 may generate a read bias voltage corresponding to the first read bias and supply the generated read bias voltage to the memory cell array 640. The program/read circuit 660 may output the data read through the read circuit 665 to the controller 500. The controller 500 may compare the number of the cells (e.g., erased cells) that are read in the memory device 550 with the reference cell number, analyze the comparison result, and determine the adequacy based on the analyzed comparison result. Herein, if the number of the cells that are read is out of an adequate range (i.e., the reference cell number), in other words, if the number of the cells that are read is out of the error tolerance range, the controller 500 may determine a voltage control signal for offsetting a read bias in a positive direction or a negative direction (i.e., a voltage control signal for adjusting a read bias voltage), and output the determined voltage control signal to the memory device 550. The memory device 550 may generate a new read bias based on the adjusted voltage control signal.

Subsequently, the controller 500 may analyze the number of the cells that are read based on the read bias voltage adjusted in the memory device 550. That is, the controller 500 may compare the number of the cells that are read with the reference cell number. If it is determined that the adjusted read bias voltage is an adequate read bias voltage, the controller 500 may control the read operation of the memory device 550 based on the adjusted read bias voltage.

It is noted that in an embodiment the memory device 550 of FIG. 5 may include a plurality of memory blocks arranged as in the embodiments of FIGS. 1 to 4.

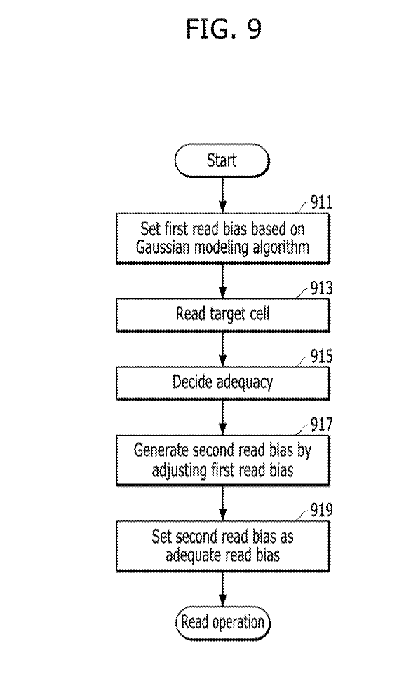

FIGS. 7A to 7C are diagrams illustrating threshold voltage distributions of an erased state and higher data states of a memory device in a memory system, in accordance with an embodiment of the present invention.

Referring to FIGS. 7A to 7C, the memory cells of the memory device 550 may be programmed, and accordingly, the threshold voltages of the memory cells may be in the ranges that represent the data states, respectively. When an erase operation is performed, the memory cells may be in the erased state E. When a program operation is performed, the memory cells may be programmed with a higher voltage level to represent the data states. FIG. 7A shows an example where a Single-Level Cell (SLC) is programmed, and FIG. 7B shows an example where a Multi-Level Cell (MLC) is programmed. For example, in FIG. 7B, the memory cells may be programmed with a threshold voltage whose level is higher than that of an erased cell to represent the data states P1, P2 or P3 in the program operation of the memory device 550.

In FIGS. 7A to 7C, the x-axis may represent a threshold voltage Vth, while the y-axis may represent the number of the memory cells #Cell. For example, there are two states in FIG. 7A and each of the two states may represent a threshold voltage distribution: an erased state E 710, and a programmed state P1 712. For example, there are four states in FIG. 7B and each of the four states may represent a threshold voltage distribution: an erased state E 720, a programmed state P1 722, a programmed state P2 724, and a programmed state P3 726. Also, the memory device 550 having additional data states, such as the 8 states which are shown in FIG. 7C or more states, e.g., 16 states, may be used.

The controller 500 may perform an operation of re-determining (i.e., re-determining) a target read bias in a predetermined condition. The predetermined condition may include passing of a predetermined time, an increase in a data error rate, and a read operation failure. The adequacy determination unit 510 of the controller 500 may calculate the error rate of the target read bias, and perform a first read bias determination operation based on the calculated error rate. For example, while a normal read operation is being performed, the controller 500 may determine a read bias based on a gradient descent algorithm, and control the read operation of the memory device 550 based on the determined read bias. The controller 500 then may determine whether the read bias is adequate or not while performing the read operation. When the read bias is away from the optimal read bias of the target threshold voltage distributions, the controller 500 may perform the first read bias determination operation by performing a Gaussian modeling algorithm.

When the adequacy determination unit 510 determines that the target read bias for the target threshold voltage distributions is inadequate, the read bias determination unit 520 may then determine the first read bias of the read operation to be performed for the target threshold voltage distributions. The read bias determination unit 520 may determine the first read bias based on the Gaussian modeling algorithm GM_ARG. The read bias determination unit 520 may determine the first read bias to be approximate the optimal read bias of the target threshold voltage distributions.

According to an embodiment of the present invention, the read bias determination unit 520 may determine a mean threshold voltage of a first target threshold voltage distribution that is selected among the target threshold voltage distributions based on a Gaussian distribution function, and determine the first read bias based on the mean threshold voltage and the estimated width of the first target threshold voltage distribution.

According to an embodiment of the present invention, the read bias determination unit 520 may perform the first read bias determination operation for the same target threshold voltage distributions multiple times based on the Gaussian modeling algorithm GM_ARG while time passes by. Herein, the read bias determination unit 520 may calculate a plurality of first read biases for the same target threshold voltage distributions. Therefore, the read bias determination unit 520 may determine a mean of the first read biases that are calculated for the same target threshold voltage distributions while time passes by as a new first read bias.

According to an embodiment of the present invention, the initial bias may be the first read bias SV that is positioned at the boundary between an erased cell and a programmed cell, as illustrated in FIGS. 7A to 7C.

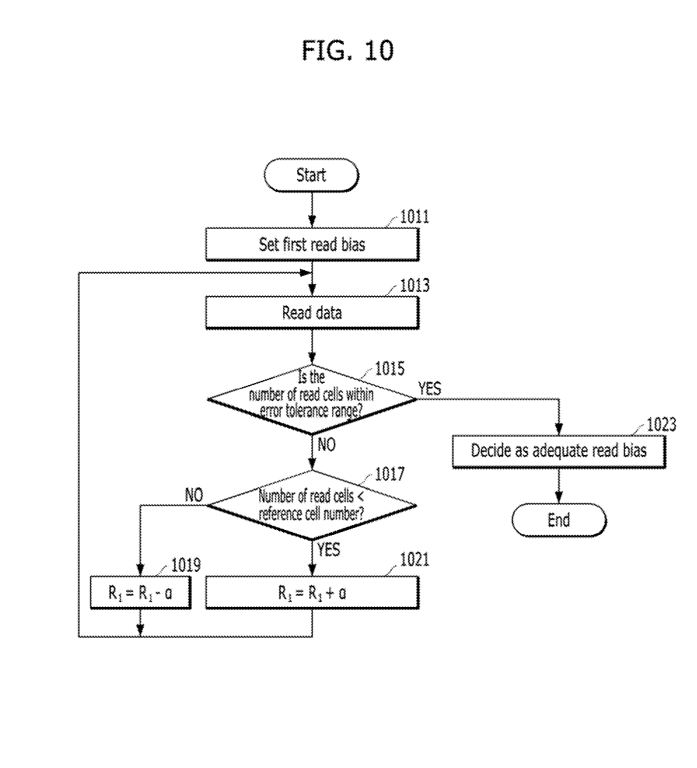

FIGS. 8A to 8C are diagrams illustrating an operation for determining a first read bias in the memory system, in accordance with an embodiment of the present invention.

Referring to FIG. 8A, the read bias determination unit 520 may calculate a mean threshold voltage m1 of the threshold voltage distribution 820 and estimate the width w1 of the threshold voltage distribution 820. The read bias determination unit 520 may set the first read bias SV1 based on the mean threshold voltage m1 and the estimated width w1 of the threshold voltage distribution 820. For example, as illustrated in FIG. 8A, the first read bias SV1 may be set by shifting the mean threshold voltage m1 to the left side of the threshold voltage distribution 820 as much as the estimated width w1. In FIG. 8A, the threshold voltage distribution 810 of the erased cells E and the threshold voltage distribution 820 of the programmed cells P do not overlap with each other.

When the first read bias SV1 is set, the controller 500 may transfer a voltage control signal based on the first read bias SV1, a read command, and address information to the memory device 550. The memory device 550 may generate a read bias voltage based on the received voltage control signal, and may perform a read operation onto the target memory cells of the memory cell array 640 based on the read command, the address information, and the generated read bias voltage. The data that are read in the memory device 550 may be transferred to the controller 500.

The controller 500 may compare the number of cells of the received data with the predetermined number of reference cells, analyze the comparison result, and determine whether the read bias determined based on the first read bias SV1 is adequate or not. The adequacy determination unit 510 may determine the number of the target memory cells (i.e., the number of the cells that are read based on the first read bias voltage) that are determined to have smaller threshold voltage than the first read bias SV1. When the first read bias SV1 is applied to the target memory cells of the memory cell array 640, the adequacy determination unit 510 may determine the number of the memory cells that are turned on as the number of the cells having a smaller threshold voltage than the first read bias SV1. For example, the adequacy determination unit 510 may set the number of the cells that are read based on the first bias voltage that are determined to have smaller threshold voltage than the first read voltage by obtaining the data that are read from the target memory cells when the first read bias SV1 is applied to the target memory cells and counting a predetermined value (e.g., ‘1’) from the obtained data.

The adequacy determination unit 510 may determine the number of cells determined to have smaller threshold voltage than the first read voltage and also may determine a reference cell number and compare the two numbers. When the number of the memory cells corresponding to the threshold voltage distributions is uniform, the reference cell number may be the number of the target memory cells that are estimated to have a smaller threshold voltage than the first read bias SV1. In other words, when the number of the memory cells corresponding to the threshold voltage distributions is uniform, the reference cell number may be the number of the erased cells that are estimated to be turned on when the first read bias SV1 is applied to the target memory cells. Therefore, the reference cell number may be determined based on the first read bias SV1 or the target threshold voltage distributions.

The adequacy determination unit 510 may determine whether the first read bias SV1 is adequate or not based on the number of cells determined to have smaller threshold voltage than the first read voltage and the reference cell number. The adequacy determination unit 510 may determine whether the first read bias SV1 is adequate or not based on the following Equation 1. The Equation 1 represents an error rate between the number cells determined to have smaller threshold voltage than the first read voltage and the reference cell number. When the error rate falls within an error tolerance range, the adequacy determination unit 510 may determine that the first read bias is an adequate read bias. As the error rate becomes smaller, the first read bias gets closer to an optimal read bias.

Error Rate=(Number of cells determined to have smaller threshold voltage than the first read voltage−reference cell number)/(Number of target memory cells for each threshold voltage distribution) (1)

For example, when it is assumed that the number of the erased cells E is approximately 100, the number of the programmed cells P is approximately 100 and the error tolerance range ranges from approximately 0.9 to 1.1, the reference cell number may be approximately 100. Therefore, when the number of the cells which are determined to have a smaller threshold voltage than the first read voltage is sensed to be from about 90 to about 110, the adequacy determination unit 510 may determine that the first read bias SV1 is an adequate read bias.

The read bias determination unit 520 may estimate a peak point of the threshold voltage distributions 820 (e.g., a mean threshold voltage m), and determine a point that is away from the estimated peak point by a predetermined value (e.g., an estimated width w) as the first read bias. Therefore, when the threshold voltages of the erased cells E and the programmed cells P do not overlap with each other as shown in FIG. 8A, the adequacy determination unit 510 may determine the first read bias SV1 that is determined in the read bias determination unit 520 as an adequate read bias.

However, the erase state and the program state may have a threshold voltage that is included in one state. For example, when the erase state distribution shifts as shown in FIG. 8B (when threshold voltage distributions 830 of the erased cells E overlap with threshold voltage distributions 840 of the programmed cells P), a first read bias SV2 of a read bias determination unit 520 based on the Gaussian modeling algorithm may be out of the optimal position. Referring to FIG. 8B, the read bias determination unit 520 may determine the first read bias SV2 based on the mean threshold voltage m2 and the estimated width w2. Herein, if the threshold voltage distribution 840 of the programmed cells P is the same as the threshold voltage distribution 820 of FIG. 8A, the mean threshold voltage m2 and the estimated width w2 may be the same as the mean threshold voltage m1 and the estimated width w1, respectively. Also, the first read bias SV2 may be the same as the first read bias SV1, too. However, when the threshold voltage distributions 830 of the erase state is raised (increased), the first read bias SV2 may include the threshold voltage distributions 830 of the erased cells E.

The controller 500 may transfer a voltage control signal based on the determined first read bias SV2 to the memory device 550, and the memory device 550 may generate a read bias based on the received voltage control signal. Herein, the read bias may be set as the first read bias SV2, and thus, a target cell region that is set based on the first read bias SV2 may include erased cells. For example, each of the memory cells of the SLC region shown in FIG. 7A may have a threshold voltage distribution included in one state between the erased state E and the programmed state P based on the value of a programmed data. For example, each of the memory cells of the 2-bit MLC region shown in FIG. 7B may have threshold voltage distributions included in one state between the erased state E and the first to third programmed states P1 to P3 based on the value of a programmed data.

When the memory device 550 performs a read operation based on the first read bias SV2 that is determined in the state shown in FIG. 8B, the memory device 550 may read and output some of the erased cells. The controller 500 then may determine the number of cells that are read in the memory device 550, and determine whether the first read bias SV2 is adequate or not. In the case of FIG. 8B, the number of the cells that are positioned on the left side of the first read bias SV2 may be smaller than the reference cell number, and the adequacy determination unit 510 may determine that the first read bias SV2 is out of the error tolerance range which is set based on the Equation 1.

When the first read bias SV2 is set out of the error tolerance range, the controller 500 may offset the first read bias SV2 in proportion to the number of the cells which are determined to have a smaller threshold voltage than the first read bias SV2 and the reference cell number. Referring to FIG. 8C, the controller 500 may determine a first read bias SV2 based on a Gaussian modeling (GM) algorithm through the read bias determination unit 520. Then, the error rate may be calculated based on the reference cell number that is set and the number of the cells which are read based on the first read bias SV2. When the error rate goes out of the error tolerance range, the read bias control unit 530 of the controller 500 may set an adjusted read bias RV by offsetting the first read bias SV2. When the number of the cells which are read based on the first read bias SV2 is smaller than the reference cell number, the read bias control unit 530 may generate a second read bias by adding a positive offset to the first read bias SV2. When the number of the cells which are read based on the first read bias SV2 is greater than the reference cell number, the read bias control unit 530 may generate a second read bias by adding a negative offset to the first read bias SV2. The controller 500 may control the read operation of the memory device 550 based on the second read bias.

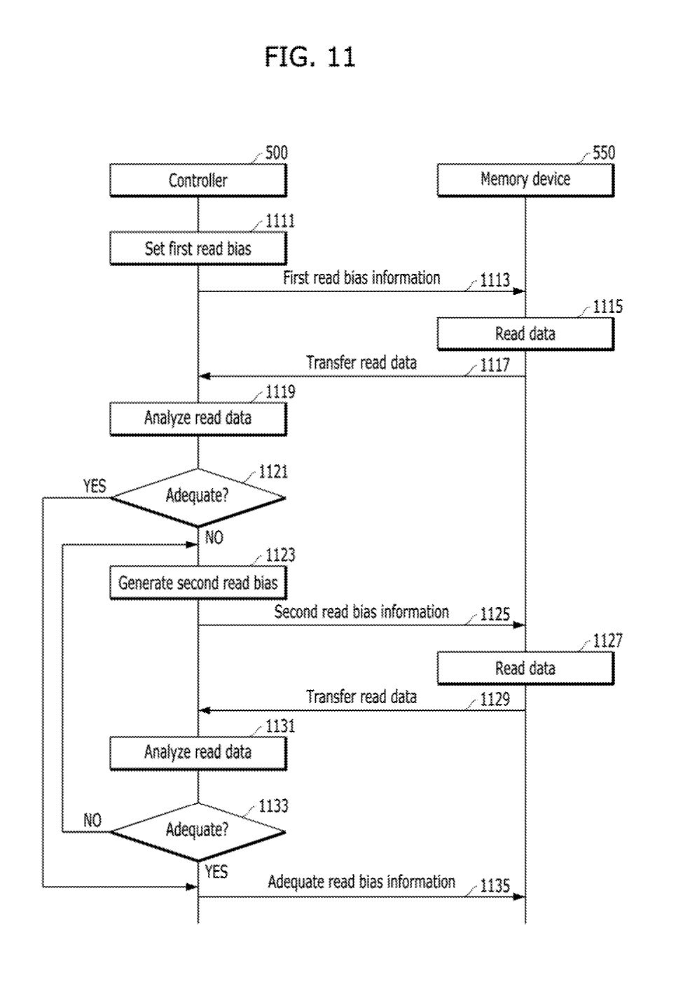

FIG. 9 is a flowchart illustrating an operation for determining a read bias in the memory system, in accordance with an embodiment of the present invention.

Referring to FIG. 9, in step 911, the memory system may determine a first read bias. The first read bias may be determined when a read bias is determined to be inadequate due to a read disturbance or read failure. The memory system may determine the first read bias based on the Gaussian modeling algorithm. The first read bias may be a read bias that is used for distinguishing erased cells and programmed cells from each other. When the first read bias is decided, in step 913, the memory system may read target cells of a memory cell array based on the first read bias.

After the target cells are read, in step 915, the memory system may analyze a result of a read operation for the target cells and determine whether the first read bias is adequate or not. The memory system may determine whether a target read bias for target threshold voltage distributions is adequate or not. Herein, the target read bias may be the first read bias. The first read bias may be a read bias for distinguishing the erased cells and the programmed cells from each other. The target threshold voltage distributions may be threshold voltage distributions that are adjacent to each other among the threshold voltage distributions of the memory cells. According to an embodiment of the present invention, the neighboring threshold voltage distributions may be the threshold voltage distributions of the erased cells and the threshold voltage distributions of the programmed cells. The target threshold voltage distributions may be the neighboring threshold voltage distributions that have to be grouped as the first read bias. In other words, an adequacy determination operation may be an operation for determining whether the first read bias is adequately positioned between the target threshold voltage distributions in such a manner that the neighboring target threshold voltage distributions of the erased cells and programmed cells are distinguished.

In the step 915, the memory system may calculate an error rate of the target read bias of the target threshold voltage distributions with respect to the first read bias and determine whether the target read bias is within the error tolerance range for the optimal read bias based on the calculated error rate. The optimal read bias may be a voltage level corresponding to a valley of the target threshold voltage distributions. The memory system may determine that the first read bias is adequate when the first read bias is within the error tolerance range for the optimal read bias. When the memory system determines that the first read bias is adequate, the memory system may then determine the first read bias as a read bias and control the read operation of the memory device 550.

However, when the first read bias is not within the error tolerance range for the optimal read bias, that is, when the first read bias is determined to be inadequate, in step 917, the memory system may generate a second read bias by adjusting the first read bias in such a manner that the first read bias is within the error tolerance range of the optimal read bias. For example, when the threshold voltage distributions 830 corresponding to the erased state E and the threshold voltage distributions 840 corresponding to the programmed state P overlap with each other as shown in FIG. 8B, the first read bias may include the threshold voltage distributions 830 of the erased cells. As shown in FIG. 8B, the number of cells that are read based on the first read bias SV2 may go out of the error tolerance range. When the number of cells that are read based on the first read bias SV2 is out of the error tolerance range, in the step 917, the memory system may generate a second read bias by checking out the number of cells that are read based on the first read bias SV2, calculating an error rate by comparing the number of cells which were read using the first read bias SV2 with the reference cell number, and adjusting the first read bias SV2 based on the calculated error rate. For example, the memory system may adjust the first read bias SV2 by offsetting the first read bias SV2 in a positive direction based on the error rate when the number of cells which were read with the first read bias SV2 is smaller than the reference cell number. Alternatively, the memory system may adjust the first read bias SV2 by offsetting the first read bias SV2 in a negative direction based on the error rate when the number of cells which was read using the first read bias SV2 is greater than the reference cell number.

In step 919, the memory system may set a read bias of the memory device 550 based on the second read bias. The memory device 550 may perform a read operation on the memory cell array based on the read bias that is set. Also, the memory system may further perform an operation of determining an adequacy by analyzing the read data of the target cells that are read in the memory device based on the second read bias.

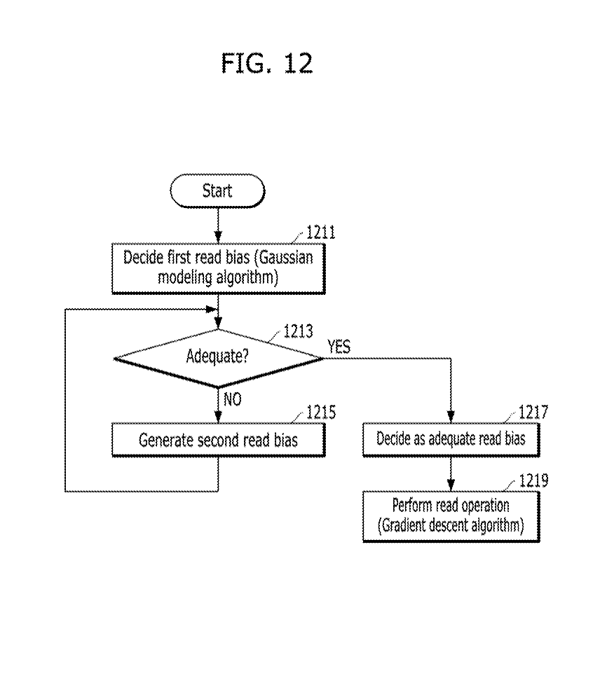

FIG. 10 is a flowchart illustrating an operation for determining a first read bias in the memory system, in accordance with an embodiment of the present invention.

Referring to FIG. 10, in step 1011, the memory system may determine a first read bias that is positioned among programmed cells that are adjacent to erased cells based on the Gaussian modeling algorithm. In an embodiment, the memory system may determine a mean threshold voltage distribution m of the programmed cells, estimate a width w of the threshold voltage distributions of the programmed cells, and determine a first read bias that distinguishes the threshold voltage distributions of the programmed cells and the threshold voltage distributions of the erased cells based on the mean threshold voltage distribution m and the estimated width w.

After determining the first read bias, in step 1013, the memory system may control a read operation of target cells of the memory device 550 based on the first read bias. Subsequently, the memory system may calculate an error rate of the first read bias in the same method as the above Equation 1 by using the number of read cells that are read in the memory device 550 and the reference cell number. For example, the error rate may be determined based on the number of the read cells, which is the number of the cells that are positioned on the left side of the first read bias, and the reference cell number. In step 1015, the memory system may determine the first read bias as an adequate read bias, when the number of the read cells is within an error tolerance range or when the number of the read cells is equal to the reference cell number. When the number of the read cells is within the error tolerance range (step 1015, YES), in step 1023, the memory system may determine a corresponding bias as a read bias, and may control the read operation of the memory device 550 based on the determined read bias.

Conversely, when the number of the read cells is out of the error tolerance range (step 1015, NO), in step 1017, the memory system may compare the number of the read cells with the reference cell number and analyze the comparison result. When the number of the read cells is out of the error tolerance range and smaller than the reference cell number (step 1017, YES), in step 1021, the memory system may generate a second read bias by adjusting the first read bias as much as an offset value a in a positive direction. When the number of the read cells is out of the error tolerance range and greater than the reference cell number (step 1017, NO), in step 1019, the memory system may generate a second read bias by adjusting the first read bias as much as an offset value a in a negative direction. Herein, the offset value a may be positioned within the error tolerance range of the optimal read bias, and the offset value a may be determined based on the error rate.

After generating the second read bias by analyzing the number of the cells that are read based on the first read bias and offsetting the first read bias, the memory system may control the read operation of the memory device 550 based on the second read bias in the step 1013 and may then perform the operations of the steps 1015 to 1023.

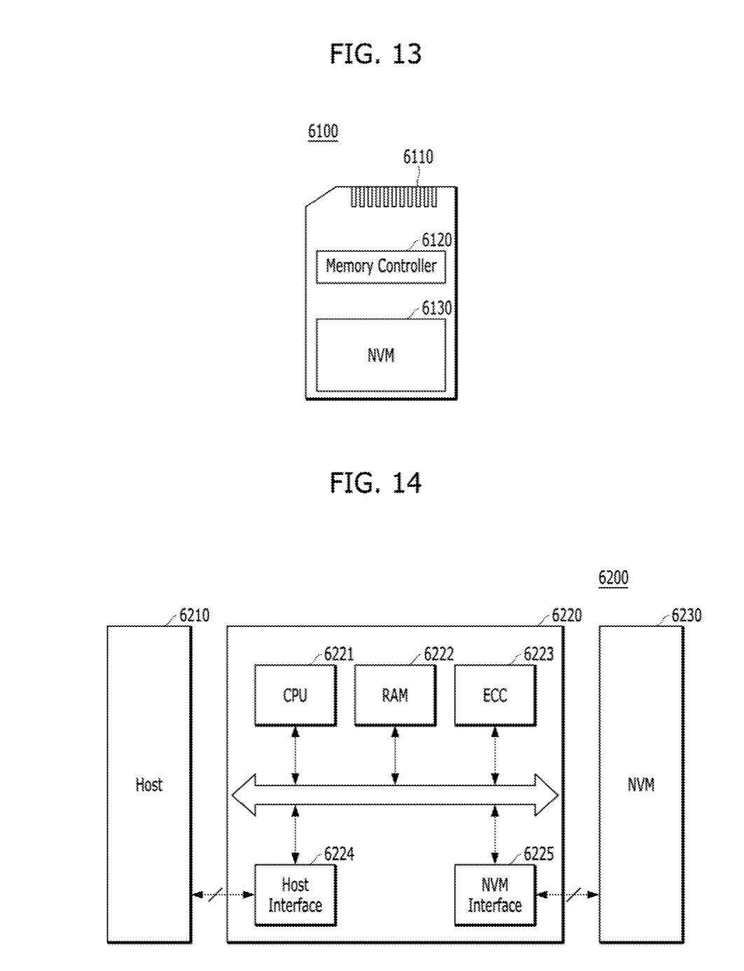

FIG. 11 is a flowchart illustrating an operation for determining a read bias between the controller 500 and the memory device 550 in the memory system, in accordance with an embodiment of the present invention.

Referring to FIG. 11, in step 1111, the controller 500 may determine a first read bias. The operation of determining the first read bias may be performed during an initial read operation or when a target read bias is determined to be inadequate in the middle of performing a read operation. The controller 500 may determine the first read bias to approximate the optimal read bias of the target threshold voltage distributions based on the Gaussian modeling algorithm GM_ARG. In an embodiment, the controller 500 may determine a mean threshold voltage of the target threshold voltage distribution of the cells that are programmed at the positions adjacent to the erased cells based on a Gaussian distribution function, and determine an initial bias that is positioned in the boundary between the erased cells and the programmed cells based on the mean threshold voltage and an estimated width.

In step 1113, the controller 500 may transfer information on the determined first read bias to the memory device 550. In step 1115, the memory device 550 may generate a read bias voltage based on the received information on the first read bias, and may perform a read operation on target memory cells based on the generated read bias voltage. In step 1117, the memory device 550 may transfer the read data of the target memory cells to the controller 500.

In step 1119, the controller 500 may analyze the read data. The analyzing method may include detecting the number of the read cells, which are the cells that are positioned on the left side of the first read bias, among the read cell data, and comparing the number of the read cells with the reference cell number, and analyzing the comparison result. In this way, whether the first read bias is adequate or not may be determined. The controller 500 may determine the first read bias as an adequate read bias, when the number of read cells is within the error tolerance range of the reference cells. Otherwise, the controller 500 may determine the first read bias as an inadequate read bias. Therefore, when the first read bias is determined to be an inadequate read bias (step 1121, NO), in step 1123, the controller 500 may generate a second read bias by offsetting the first read bias. When the number of the read cells is smaller than the reference cell number, the controller 500 may adjust the first read bias by offsetting the first read bias in a positive direction based on the error rate. When the number of the read cells is greater than the reference cell number, the controller 500 may adjust the first read bias by offsetting the first read bias in a negative direction based on the error rate.

According to an embodiment of the present invention, the controller 500 may control a read operation by setting a second read bias as an optimal read bias and transferring the second read bias to the memory device 550. The memory device 550 may then generate a read bias voltage based on the second read bias that is transferred from the controller 500, and may perform a read operation based on the generated read bias voltage.

According to an embodiment of the present invention, the controller 500 may repeat the determination of whether the second read bias is adequate or not. In step 1125, the controller 500 may transfer the second read bias to the memory device 550. In step 1127, the memory device 550 may then generate a read bias voltage corresponding to the second read bias, and perform a read operation based on the generated read bias voltage. In step 1129, the memory device 550 may transfer a read data to the controller 500. In step 1131, the controller 500 may analyze the read data. In step 1133, the controller 500 may determine whether the second read bias is an adequate read bias or not. The operation of the steps 1125 to 1133 may be performed in the same manner as that of the steps 1113 to 1121.

When the first read bias or the second read bias that is analyzed in the steps 1121 or 1133 is determined to be an adequate read bias, in step 1135, the controller 500 may set a read bias, and transfer the read bias to the memory device 550. The memory device 550 may generate a read bias voltage corresponding to the read bias that is set, and may perform a read operation based on the generated read bias voltage.

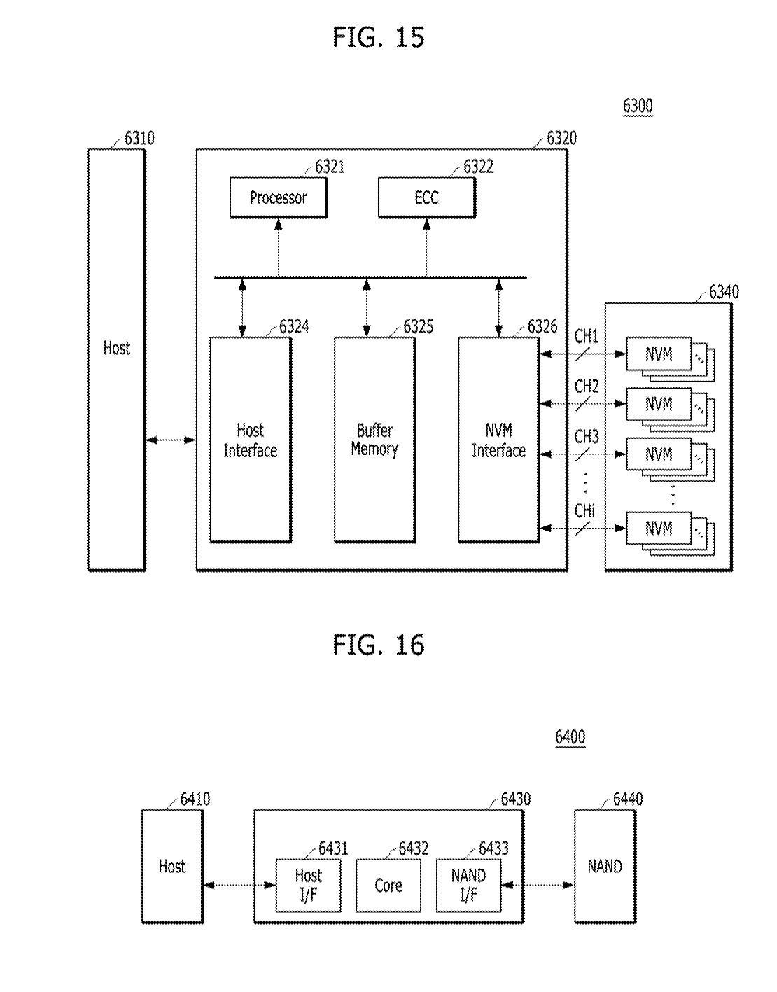

FIG. 12 is a flowchart illustrating a process of performing a read operation in the memory system, in accordance with an embodiment of the present invention.

Referring to FIG. 12, in step 1211, the controller 500 may determine a first read bias to be used for an operation of determining a read bias for target threshold voltage distributions based on the Gaussian modeling algorithm GM_ARG. The controller 500 may determine a first read bias to approximate the optimal read bias of the target threshold voltage distributions. For example, the read bias determination unit 520 of FIG. 5 may determine a mean threshold voltage of a selected target threshold voltage distribution among the target threshold voltage distributions based on the Gaussian distribution function, and determine a first read bias based on the mean threshold voltage m1 and an estimated width of the selected target threshold voltage distribution. The target threshold voltage distributions may be threshold voltage distributions of the programmed cells that are positioned adjacent to the erased cells. The first read bias may be positioned at the boundary (which is a valley) between the erased cells and the programmed cells.

After determining the first read bias, in step 1213 the controller 500 may determine whether the first read bias is adequate or not for the target threshold voltage distributions. When it is determined that the first read bias is an inadequate read bias (step 1213, NO), in step 1215, the controller 500 may generate a second read bias by adjusting the first read bias. The method for generating the second read bias may include comparing the number of the cells that are positioned on the left side of the first read bias with the number of reference cells (i.e., the reference cell number) and offsetting the first read bias in a positive direction or a negative direction as may be needed. After adjusting the first read bias, in step 1213, the controller 500 may determine the adequacy for the adjusted first read bias as the second read bias. When it is determined that the second read bias is an adequate read bias (step 1213, YES), in step 1217, the controller 500 may determine the second read bias as a read bias. Subsequently, in step 1219, the controller 500 may control a read operation of the memory device 550 based on the determined read bias.

When the controller 500 controls the read operation in the step 1219, the controller 500 may determine a new read bias for target threshold voltage distributions based on the Gradient Descent Algorithm GD_ARG.

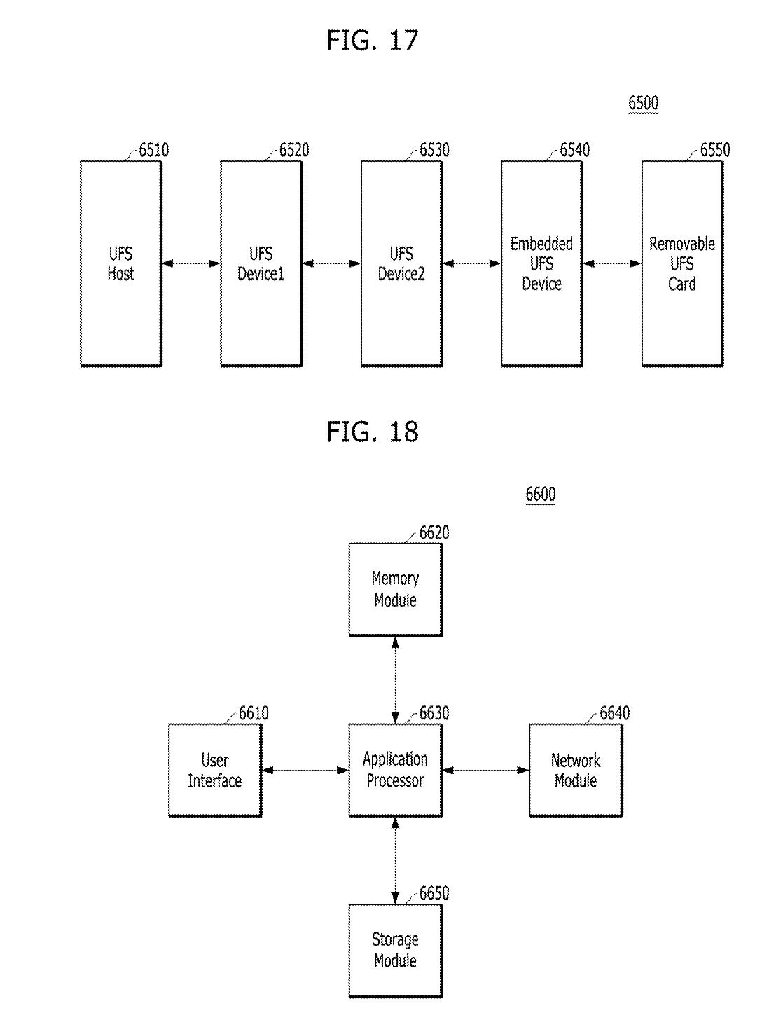

Hereinbelow, detailed descriptions will be made with reference to FIGS. 13 to 18, for a data processing system and electronic appliances to which the memory system 110 including the memory device 150 and the controller 130 described above with reference to FIGS. 1 to 12, according to an embodiment may be applied.

FIG. 13 is a diagram illustrating a data processing system including the memory system according to an embodiment. Specifically, FIG. 13 illustrates a memory card system 6100 to which the memory system according to an embodiment is applied.

Referring to FIG. 13, the memory card system 6100 may include a memory controller 6120, a memory device 6130, and a connector 6110.

The memory controller 6120 may be connected with the memory device 6130 and may access the memory device 6130. In an embodiment, the memory device 6130 may be implemented with a nonvolatile memory (NVM). For example, the memory controller 6120 may control read, write, erase and background operations for the memory device 6130. The memory controller 6120 may provide an interface between the memory device 6130 and a host (not shown), and may drive a firmware for controlling the memory device 6130. For example, the memory controller 6120 may correspond to the controller 130 in the memory system 110 described above with reference to FIG. 1, and the memory device 6130 may correspond to the memory device 150 in the memory system 110 described above with reference to FIG. 1.

Therefore, the memory controller 6120 may include components such as a random access memory (RAM), a processing unit, a host interface, a memory interface and an error correction unit as shown in FIG. 1.

The memory controller 6120 may communicate with an external device (for example, the host 102 described above with reference to FIG. 1), through the connector 6110. For example, as described above with reference to FIG. 1, the memory controller 6120 may be configured to communicate with the external device through at least one of various communication protocols such as a universal serial bus (USB), a multimedia card (MMC), an embedded MMC (eMMC), a peripheral component interconnection (PCI), a PCI express (PCI-e), an Advanced Technology Attachment (ATA), a Serial-ATA, a Parallel-ATA, a small computer system interface (SCSI), an enhanced small disk interface (ESDI), an Integrated Drive Electronics (IDE), a Firewire, universal flash storage (UFS), wireless-fidelity (WI-FI) and a Bluetooth. The memory system and the data processing system may be applied to wired and/or wireless electronic appliances, for example, a mobile electronic appliance.

The memory device 6130 may be implemented with a nonvolatile memory (NVM). For example, the memory device 6130 may be implemented with one of various nonvolatile memory devices such as, for example, an electrically erasable and programmable ROM (EPROM), a NAND flash memory, a NOR flash memory, a phase-change RAM (PRAM), a resistive RAM (ReRAM), a ferroelectric RAM (FRAM) and a spin torque transfer magnetic RAM (STT-MRAM).

The memory controller 6120 and the memory device 6130 may be integrated into a single semiconductor device. For example, the memory controller 6120 and the memory device 6130 may construct a solid state driver (SSD) by being integrated into a single semiconductor device. The memory controller 6120 and the memory device 6130 may construct a memory card such as a PC card (e.g., Personal Computer Memory Card International Association (PCMCIA)), a compact flash card (CF), a smart media card (e.g., SM and SMC), a memory stick, a multimedia card (e.g., MMC, RS-MMC, MMCmicro and eMMC), an SD card (e.g., SD, miniSD, microSD and SDHC) and a universal flash storage (UFS).

FIG. 14 is a diagram schematically illustrating another example of a data processing system 6200 including a memory system, according to an embodiment of the present invention.

Referring to FIG. 14, the data processing system 6200 may include a memory device 6230 which may be implemented with at least one nonvolatile memory (NVM) and a memory controller 6220 for controlling the memory device 6230. The data processing system 6200 may be a storage medium such as a memory card (e.g., CF, SD and microSD), as described above with reference to FIG. 1. The memory device 6230 may correspond to the memory device 150 in the memory system 110 described above with reference to FIG. 1, and the memory controller 6220 may correspond to the controller 130 in the memory system 110 described above with reference to FIG. 1.

The memory controller 6220 may control the operations, including the read, write and erase operations for the memory device 6230 in response to requests received from a host 6210. The memory controller 6220 may include at least one of a central processing unit (CPU) 6221, a random access memory (RAM) as a buffer memory 6222, an error correction code (ECC) circuit 6223, a host interface 6224, and an NVM interface as a memory interface 6225, all coupled via an internal bus.

The CPU 6221 may control the operations for the memory device 6230 such as read, write, file system management, bad page management, and so forth. The RAM 6222 may operate according to control of the CPU 6221, and may be used as a work memory, a buffer memory, a cache memory, or the like. In the case where the RAM 6222 is used as a work memory, data processed by the CPU 6221 is temporarily stored in the RAM 6222. In the case where the RAM 6222 is used as a buffer memory, the RAM 6222 is used to buffer data to be transmitted from the host 6210 to the memory device 6230 or from the memory device 6230 to the host 6210. In the case where the RAM 6222 is used as a cache memory, the RAM 6222 may be used to enable the memory device 6230 with a low speed to operate at a high speed.

The ECC circuit 6223 may correspond to the ECC unit 138 of the controller 130 described above with reference to FIG. 1. As described above with reference to FIG. 1, the ECC circuit 6223 may generate an error correction code (ECC) for correcting a fail bit or an error bit in the data received from the memory device 6230. The ECC circuit 6223 may perform error correction encoding for data to be provided to the memory device 6230, and may generate data added with parity bits. The parity bits may be stored in the memory device 6230. The ECC circuit 6223 may perform error correction decoding for data outputted from the memory device 6230. At this time, the ECC circuit 6223 may correct errors by using the parity bits. For example, as described above with reference to FIG. 1, the ECC circuit 6223 may correct errors by using one of various coded modulations such as a low density parity check (LDPC) code, a Bose-Chaudhuri-Hocquenghem (BCH) code, a turbo code, a Reed-Solomon (RS) code, a convolution code, a recursive systematic code (RSC), a trellis-coded modulation (TCM) and a Block coded modulation (BCM).

The memory controller 6220 may transmit and receive data to and from the host 6210 through the host interface 6224, and transmit and receive data to and from the memory device 6230 through the NVM interface 6225. The host interface 6224 may be connected with the host 6210 through at least one of various interface protocols such as a parallel advanced technology attachment (PATA) bus, a serial advanced technology attachment (SATA) bus, a small computer system interface (SCSI), a universal serial bus (USB), a peripheral component interconnection express (PCI-e) or a NAND interface. Further, as a wireless communication function or a mobile communication protocol such as wireless fidelity (WI-FI) or long term evolution (LTE) is implemented, the memory controller 6220 may transmit and receive data by being connected with an external device such as the host 6210 or another external device other than the host 6210. Specifically, as the memory controller 6220 is configured to communicate with an external device through at least one among various communication protocols, the memory system and the data processing system according to the embodiment may be applied to wired and/or wireless electronic appliances, for example, a mobile electronic appliance.

FIG. 15 is a diagram illustrating another example of a data processing system including a memory system, according to an embodiment of the invention. For example, in FIG. 15, a solid state drive (SSD) 6300 employing a memory system is shown.

Referring to FIG. 15, the SSD 6300 may include a memory device 6340 which may include a plurality of nonvolatile memories NVM, and a controller 6320. The controller 6320 may correspond to the controller 130 in the memory system 110 described above with reference to FIG. 1, and the memory device 6340 may correspond to the memory device 150 in the memory system 110 described above with reference to FIG. 1.

The controller 6320 may be connected with the memory device 6340 through a plurality of channels CH1, CH2, CH3, . . . and CHi. The controller 6320 may include a processor 6321, a buffer memory 6325, an error correction code (ECC) circuit 6322, a host interface 6324, and a nonvolatile memory (NVM) interface as a memory interface 6326 coupled via an internal bus.

The buffer memory 6325 may temporarily store data received from a host 6310 or data received from a plurality of nonvolatile memories NVMs included in the memory device 6340, or temporarily store metadata of the plurality of nonvolatile memories NVMs. For example, the metadata may include map data including mapping tables. The buffer memory 6325 may be implemented with a volatile memory such as, but not limited to, a dynamic random access memory (DRAM), a synchronous dynamic random access memory (SDRAM), a double data rate (DDR) SDRAM, a low power double data rate (LPDDR) SDRAM and a graphic random access memory (GRAM) or a nonvolatile memory such as, but not limited to, a ferroelectric random access memory (FRAM), a resistive random access memory (ReRAM), a spin-transfer torque magnetic random access memory (STT-MRAM) and a phase change random access memory (PRAM). While it is illustrated in FIG. 10, for the sake of convenience in explanation, that the buffer memory 6325 is disposed inside the controller 6320, it is to be noted that the buffer memory 6325 may be disposed outside the controller 6320.

The ECC circuit 6322 may calculate error correction code values of data to be programmed in the memory device 6340 in a program operation, perform an error correction operation for data read from the memory device 6340, based on the error correction code values, in a read operation, and perform an error correction operation for data recovered from the memory device 6340 in a recovery operation for failed data.

The host interface 6324 may provide an interface function with respect to an external device such as the host 6310. The nonvolatile memory interface 6326 may provide an interface function with respect to the memory device 6340 which is connected through the plurality of channels CH1, CH2, CH3, . . . and CHi.

As a plurality of SSDs 6300 to each of which the memory system 110 described above with reference to FIG. 1 is applied are used, a data processing system such as a redundant array of independent disks (RAID) system may be implemented. In the RAID system, the plurality of SSDs 6300 and an RAID controller for controlling the plurality of SSDs 6300 may be included. In the case of performing a program operation by receiving a write command from the host 6310, the RAID controller may select at least one memory system (for example, at least one SSD 6300) in response to the RAID level information of the write command received from the host 6310, among a plurality of RAID levels (for example, the plurality of SSDs 6300) and may output data corresponding to the write command, to the selected SSD 6300. In the case of performing a read operation by receiving a read command from the host 6310, the RAID controller may select at least one memory system (for example, at least one SSD 6300) in response to the RAID level information of the write command received from the host 6310, among the plurality of RAID levels (for example, the plurality of SSDs 6300), and may provide data outputted from the selected SSD 6300, to the host 6310.

FIG. 16 is a diagram illustrating another example of a data processing system including the memory system, according to an embodiment of the present invention. For example, in FIG. 16, an embedded multimedia card (eMMC) 6400 employing a memory system is shown.

Referring to FIG. 16, the eMMC 6400 may include a memory device 6440 which is implemented with at least one NAND flash memory, and a controller 6430. The controller 6430 may correspond to the controller 130 in the memory system 110 described above with reference to FIG. 1, and the memory device 6440 may correspond to the memory device 150 in the memory system 110 described above with reference to FIG. 1.

The controller 6430 may be connected with the memory device 6440 through a plurality of channels. The controller 6430 may include a core 6432, a host interface 6431, and a memory interface such as a NAND interface 6433.

The core 6432 may control the operations of the eMMC 6400. The host interface 6431 may provide an interface function between the controller 6430 and a host 6410. The NAND interface 6433 may provide an interface function between the memory device 6440 and the controller 6430. For example, the host interface 6431 may be a parallel interface such as an MMC interface, as described above with reference to FIG. 1, or a serial interface such as an ultra-high speed class 1 (UHS-I)/UHS class 2 (UHS-II) and a universal flash storage (UFS) interface.

FIG. 17 is a diagram illustrating another example of a data processing system including a memory system, according to an embodiment of the present invention. For example, FIG. 17 illustrates a universal flash storage (UFS) to which the memory system according to an embodiment is applied.

Referring to FIG. 17, the UFS system 6500 may include a UFS host 6510, a plurality of UFS devices 6520 and 6530, an embedded UFS device 6540, and a removable UFS card 6550. The UFS host 6510 may be an application processor of wired and/or wireless electronic appliances, for example, a mobile electronic appliance.

The UFS host 6510, the UFS devices 6520 and 6530, the embedded UFS device 6540 and the removable UFS card 6550 may respectively communicate with external devices such as wired and/or wireless electronic appliances (for example, a mobile electronic appliance), for example, through a UFS protocol. The UFS devices 6520 and 6530, the embedded UFS device 6540 and the removable UFS card 6550 may be implemented with the memory system 110 described above with reference to FIG. 1, for example, as the memory card system 6100 described above with reference to FIG. 8. The embedded UFS device 6540 and the removable UFS card 6550 may also communicate through another protocol other than the UFS protocol. For example, the embedded UFS device 6540 and the removable UFS card 6550 may communicate through various card protocols such as, but not limited to, USB flash drives (UFDs), multimedia card (MMC), secure digital (SD), mini SD and Micro SD.

FIG. 18 is a diagram illustrating another example of a data processing system including the memory system according to an embodiment of the present invention. For example, in FIG. 18, a user system 6600 employing the memory system is shown.

Referring to FIG. 18, the user system 6600 may include a user interface 6610, a memory module 6620, an application processor 6630, a network module 6640, and a storage module 6650.

The application processor 6630 may drive components included in the user system 6600 and an operating system (OS). For example, the application processor 6630 may include controllers for controlling the components included in the user system 6600, interfaces, graphics engines, and so on. The application processor 6630 may be provided by a system-on-chip (SoC).

The memory module 6620 may operate as a main memory, a working memory, a buffer memory or a cache memory of the user system 6600. The memory module 6620 may include a volatile random access memory such as a dynamic random access memory (DRAM), a synchronous dynamic random access memory (SDRAM), a double data rate (DDR) SDRAM, a DDR2 SDRAM, a DDR3 SDRAM, a low power double data rate (LPDDR) SDRAM, an LPDDR2 SDRAM and an LPDDR3 SDRAM or a nonvolatile random access memory such as a phase change random access memory (PRAM), a resistive random access memory (ReRAM), a magnetic random access memory (MRAM) and a ferroelectric random access memory (FRAM). For example, the application processor 6630 and the memory module 6620 may be mounted by being packaged on the basis of a package-on-package (POP).

The network module 6640 may communicate with external devices. For example, the network module 6640 may support not only wired communications but also various wireless communications such as code division multiple access (CDMA), global system for mobile communication (GSM), wideband CDMA (WCDMA), CDMA-2000, time division multiple access (TDMA), long term evolution (LTE), worldwide interoperability for microwave access (WiMAX), wireless local area network (WLAN), ultra-wideband (UWB), Bluetooth, wireless display (WI-DI), and so on, and may thereby communicate with wired and/or wireless electronic appliances, for example, a mobile electronic appliance. Accordingly, the memory system and the data processing system according to the embodiment may be applied to wired and/or wireless electronic appliances. The network module 6640 may be included in the application processor 6630.

The storage module 6650 may store data such as data received from the application processor 6530, and transmit data stored therein, to the application processor 6530. The storage module 6650 may be implemented by a nonvolatile semiconductor memory device such as a phase-change RAM (PRAM), a magnetic RAM (MRAM), a resistive RAM (ReRAM), a NAND flash memory, a NOR flash memory and a 3-dimensional NAND flash memory. The storage module 6650 may be provided as a removable storage medium such as a memory card of the user system 6600 and an external drive. For example, the storage module 6650 may correspond to the memory system 110 described above with reference to FIG. 1, and may be implemented with the SSD, eMMC and UFS described above with reference to FIGS. 15 to 17.

The user interface 6610 may include interfaces for inputting data or commands to the application processor 6630 or for outputting data to an external device. For example, the user interface 6610 may include user input interfaces such as a keyboard, a keypad, a button, a touch panel, a touch screen, a touch pad, a touch ball, a camera, a microphone, a gyroscope sensor, a vibration sensor and a piezoelectric element, and user output interfaces such as a liquid crystal display (LCD), an organic light emitting diode (OLED) display device, an active matrix OLED (AMOLED) display device, a light emitting diode (LED), a speaker and a motor.

In the case where the memory system 110 described above with reference to FIG. 1 is applied to the mobile electronic appliance of the user system 6600 according to an embodiment, the application processor 6630 may control the operations of the mobile electronic appliance, and the network module 6640 as a communication module may control wired and/or wireless communication with an external device, as described above. The user interface 6610 as the display/touch module of the mobile electronic appliance displays data processed by the application processor 6630 or supports input of data from a touch panel.

According to the memory system and the method for operating the memory system in accordance with various embodiments of the present invention, when the first read bias is decided, the bias may be adjusted in such a manner that the first read bias is positioned within an error tolerance range in a distribution where erase state distribution is changed.

While the present invention has been described with respect to specific embodiments, it will be apparent to those skilled in the art that various changes and modifications may be made without departing from the spirit and scope of the invention as defined in the following claims.

What is claimed is:

1. A memory system, comprising:
a memory device; and
a controller coupled to the memory device,
wherein the controller determines a first read bias for distinguishing erased cells and programmed cells from each other,
detects the number of cells that are read in the memory device by controlling a read operation of the memory device based on the first read bias, and
when the number of the cells that are read goes out of an error tolerance range, generates a second read bias by offsetting the first read bias.

2. The memory system of claim 1, wherein the first read bias is set based on a Gaussian modeling algorithm.

3. The memory system of claim 2, wherein the first read bias has a voltage level that is lower than a threshold voltage of the programmed cells and higher than a threshold voltage of the erased cells.

4. The memory system of claim 3, wherein the controller includes:
a read bias determination unit suitable for determining the first read bias based on the Gaussian modeling algorithm;
an adequacy determination unit suitable for analyzing the number of erased cells that are read based on the first read bias and a reference cell number and determining whether the first read bias is an adequate read bias or not; and
a read bias control unit suitable for, when the first read bias is not an adequate read bias, generating the second read bias by offsetting the first read bias based on an error rate.

5. The memory system of claim 4, wherein the read bias control unit generates the second read bias by offsetting the first read bias in a positive direction when the number of the erased cells that are read is greater than the reference cell number, and
wherein the read bias control unit generates the second read bias by offsetting the first read bias in a negative direction when the number of the erased cells that are read is smaller than the reference cell number.

6. The memory system of claim 2, wherein the controller detects the number of cells that are positioned on a left side of the first read bias among the cells that are read based on the first read bias in the memory device, and
determines whether the first read bias is an adequate read bias or not by analyzing the detected number of the cells and the reference cell number.

7. The memory system of claim 6, wherein the controller generates the second read bias by offsetting the first read bias in a positive direction when the first read bias is determined to be an inadequate read bias and the detected number of the cells is greater than the reference cell number, and
wherein the controller generates the second read bias by offsetting the first read bias in a negative direction when the first read bias is determined to be an inadequate read bias and the detected number of the cells is smaller than the reference cell number.

8. The memory system of claim 7, wherein the controller is further suitable for controlling a read operation of the memory device based on the second read bias, detecting the number of cells that are positioned on a left side of the second read bias among the cells that are read in the memory device, and determining whether the second read bias is an adequate read bias or not by analyzing the detected number of the cells that are positioned on the left side of the second read bias and the reference cell number.

9. The memory system of claim 8, wherein when the first read bias or the second read bias is determined to be an adequate read bias, the controller further controls a read operation of the memory device by setting the adequate read bias as a read bias of the memory device.

10. The memory system of claim 9, wherein the controller controls the read operation of the memory device based on the set read bias, and controls the read bias based on a Gradient descent algorithm during the read operation of the memory device.

11. A memory system, comprising:
a memory device; and
a controller coupled to the memory device,
wherein the controller determines a first read bias for distinguishing erased cells and programmed cells from each other based on a Gaussian modeling algorithm,
controls a read operation of the memory device based on the first read bias,
compares the number of cells that are read in the memory device with a reference cell number that is based on the erased cells, and
when the number of the cells that are read goes out of an error tolerance range and the number of the cells that are read is smaller than the reference cell number, generates a second read bias by offsetting the first read bias in a positive direction, and
when the number of the cells that are read goes out of an error tolerance range and the number of the cells that are read is greater than the reference cell number, generates a second read bias by offsetting the first read bias in a negative direction.

12. The memory system of claim 11, wherein when the number of the cells that are read is within an error tolerance range, the controller sets the first read bias as a read bias and performs a read operation.

13. A method for operating a memory system, comprising:
determining a first read bias for distinguishing erased cells and programmed cells from each other;
controlling a read operation of a memory device based on the first read bias;
detecting the number of cells that are read in the memory device; and
when the number of the cells that are read goes out of an error tolerance range, generating a second read bias by offsetting the first read bias.

14. The method of claim 13, wherein the first read bias is set based on a Gaussian modeling algorithm.

15. The method of claim 14, wherein the first read bias has a voltage level that is lower than a threshold voltage of the programmed cells and higher than a threshold voltage of the erased cells.

16. The method of claim 15, further comprising:
determining the generated second read bias as a read bias of the memory device; and
controlling a read operation of the memory device based on the set read bias.

17. The method of claim 16, wherein the generating of the second read bias by offsetting the first read bias includes:
analyzing the number of erased cells that are read based on the first read bias and a reference cell number;
determining whether the first read bias is an adequate read bias or not; and
when the first read bias is determined to be an inadequate read bias, generating the second read bias by offsetting the first read bias based on an error rate.

18. The method of claim 17, wherein the generating of the second read bias by offsetting the first read bias further includes:
offsetting the first read bias in a positive direction when the number of the erased cells that are read based on the first read bias is greater than the reference cell number; and
offsetting the first read bias in a negative direction when the number of the erased cells that are read based on the first read bias is smaller than the reference cell number.

19. The method of claim 17, further comprising:
controlling the read operation of the memory device based on the second read bias, after the setting of the generated second read bias as the read bias of the memory device;
detecting the number of cells that are positioned on a left side of the second read bias among the cells that are read in the memory device; and
determining whether the second read bias is an adequate read bias or not by analyzing the detected number of the cells and the reference cell number.

20. The method of claim 19, wherein the controlling of the read operation further includes:
updating the read bias based on the Gradient descent algorithm.
